(19) United States
(12) Patent Application Publication
(10) Pub. No.: US 2026/0021662 A1
(43) Pub. Date: Jan. 22, 2026

(54) INKJET PRINTING APPARATUS AND INKJET PRINTING METHOD USING THE SAME

(71) Applicant: Samsung Display Co., LTD., Yongin-si (KR)

(72) Inventors: JEONGHO YI, Yongin-si (KR); Yeongjun KIM, Yongin-si (KR)

(21) Appl. No.: 19/190,126

(22) Filed: Apr. 25, 2025

(30) Foreign Application Priority Data
Jul. 22, 2024 (KR) 10-2024-0096258

(51) Int. Cl. B41J 2/175; B41J 11/06; H10K 59/12; H10K 71/13

(52) U.S. Cl. CPC B41J 2/175; B41J 11/06; H10K 59/1201; H10K 71/135

(57) ABSTRACT

An inkjet printing apparatus includes a stage, on which a substrate is disposed, a head part disposed above the stage, where the head part includes a nozzle which discharges ink, an ink supply part disposed between the stage and the head part, where an opening is defined through the ink supply part in a way such that the ink is received by the opening while overlapping the nozzle when viewed on a plane, and the ink supply part provides the ink onto the substrate through the opening, and an ink flow rate measuring part connected to the ink supply part, where ink flow rate measuring part measures a flow rate of the ink discharged through the opening.

This application claims priority to Korean Patent Application No. 10-2024-0096258, filed on Jul. 22, 2024, and all the benefits accruing therefrom under U.S.C. § 119, the content of which in its entirety is herein incorporated by reference.

### BACKGROUND

### (1) Field

Embodiments of the disclosure described herein relate to an inkjet printing apparatus and an inkjet printing method using the inkjet printing apparatus.

### (2) Description of the Related Art

In general, organic light emitting diode displays (OLEDs) that have desired luminance characteristics and viewing angle characteristics and do not include a separate light source unlike liquid crystal displays are attracting attention as next-generation flat panel displays. Because organic light emitting display devices do not include a separate light source, the organic light emitting display devices may be manufactured to have a light weight and a thin thickness. In addition, organic light emitting display devices have various other desired characteristics, such as low power consumption, high luminance, and high reaction speed.

The organic light emitting display device typically includes a plurality of light emitting elements each including an anode, an organic light emitting layer, and a cathode. Holes and electrons are injected from the anode and the cathode into an organic light emitting layer to form excitons, and the light emitting element emits light as the excitons transition to a ground state.

When a light emitting element is manufactured, an organic light emitting layer may be manufactured by an inkjet printing apparatus. An organic material (or ink) for forming the organic light emitting layer may be discharged from the inkjet printing apparatus onto the substrate to form an organic light emitting layer.

### SUMMARY

When an organic light emitting display device is manufactured, a high-resolution precise patterning process may be desired. As a pixel size of an organic light emitting display device having a high resolution decreases, the inkjet printing apparatus may be desired to discharge a smaller amount of ink. When the amount of ink discharged from the inkjet printing apparatus is not finely controlled, a defective organic light emitting layer is manufactured. Accordingly, it may be desired to develop an inkjet printing apparatus, in which the amount of ink may be finely controlled.

Embodiment of the disclosure is to provide an inkjet printing apparatus in which a defect rate of an organic light emitting layer may be reduced.

According to an embodiment, an inkjet printing apparatus includes a stage, on which a substrate is disposed, a head part disposed above the stage, where the head part includes a nozzle which discharges ink, an ink supply part disposed between the stage and the head part, where an opening is defined through the ink supply part in a way such that the ink is received by the opening while overlapping the nozzle when viewed on a plane, and the ink supply part provides the ink onto the substrate through the opening, and an ink flow rate measuring part connected to the ink supply part, where ink flow rate measuring part measures a flow rate of the ink discharged through the opening.

In an embodiment, a width of the opening in a horizontal direction parallel to an upper surface of the ink supply part may gradually increase as going downward.

In an embodiment, an inner surface of the ink supply part defining the opening may include an inclined surface.

In an embodiment, the inner surface of the ink supply part defining the opening may form an acute angle with a lower surface of the ink supply part.

In an embodiment, the inner surface of the ink supply part defining the opening may form an angle in a range of about 50 degrees to about 70 degrees with the lower surface of the ink supply part.

In an embodiment, when viewed on the plane, the opening may have a circular shape.

In an embodiment, the ink supply part may include metal.

In an embodiment, the inkjet printing apparatus may further include a pressure applying part disposed to contact an upper surface of the ink supply part, where pressure applying part applies a pressure to the opening.

In an embodiment, the inkjet printing apparatus may further include a controller which controls the pressure applying part to adjust the pressure applied to the opening based on the flow rate of the ink.

In an embodiment, the ink discharged through the opening may be provided to a pixel opening defined in a pixel definition layer disposed on the substrate, and a width of a lower side of the opening defined on a lower surface of the ink supply part may be smaller than a width of the pixel opening.

In an embodiment, after the ink is discharged N times from the opening, the ink remaining in the ink supply part may be removed to a lower side of the ink supply part based on the pressure of the pressure applying part, where N is a natural number of 2 or greater.

In an embodiment, an amount of the ink discharged once from the opening may be smaller than an amount of the ink discharged once from the nozzle.

In an embodiment, a ground voltage may be applied to the stage, and a high voltage having a higher level than the ground voltage may be applied to the ink supply part.

In an embodiment, the inkjet printing apparatus may further include an ultrasonic wave applying part disposed on an upper surface of the ink supply part, where the ultrasonic wave applying part applies ultrasonic waves to the ink.

According to an embodiment, an inkjet printing method includes disposing a head part including a nozzle above an ink supply part, in which an opening is defined, providing ink discharged from the nozzle to the opening of the ink supply part, disposing a pressure applying part on an upper surface of the ink supply part, and discharging the ink from the opening toward a substrate by applying a pressure to the opening through the pressure applying part, a width of the opening in a horizontal direction being parallel to an upper surface of the ink supply part may gradually increase as going downward.

In an embodiment, an inner surface of the ink supply part defining the opening may include an inclined surface, and the inner surface of the ink supply part defining the opening may form an acute angle with a lower surface of the ink supply part.

In an embodiment, an amount of the ink discharged once from the opening may be smaller than an amount of the ink discharged once from the nozzle.

In an embodiment, the inkjet printing method may further include after the ink is discharged N times from the opening, removing the ink remaining in the ink supply part to a lower side of the ink supply part based on the pressure of the pressure applying part, where N is a natural number of 2 or greater.

In an embodiment, the ink discharged through the opening may be provided to a pixel opening defined in a pixel definition layer disposed on the substrate, and a width of a lower side of the opening defined on a lower surface of the ink supply part may be smaller than a width of the pixel opening.

In an embodiment, the inkjet printing method may further include before the ink is discharged to the substrate, preventing the ink from being discharged, by applying a negative pressure to the opening through the pressure applying part.

### BRIEF DESCRIPTION OF THE DRAWINGS

The above and other features of embodiments of the disclosure will become apparent by describing in detail embodiments thereof with reference to the accompanying drawings.

FIG. 1 is a view illustrating a configuration of an inkjet printing apparatus according to an embodiment of the disclosure.

FIG. 2A is a cross-sectional view of an ink supply part taken along line I-I′ illustrated in FIG. 1.

FIG. 2B is an enlarged view of any one opening illustrated in FIG. 2.

FIG. 3 is a view illustrating cross sections of an ink storage part, a head part, and an ink supply part illustrated in FIG. 1 by way of example.

FIG. 4 is a view illustrating a cross section of a pressure applying part and an ink supply part illustrated in FIG. 1 by way of example.

FIG. 5 is a cross-sectional view of an opening of an ink supply part illustrated in FIG. 4, when viewed from a first direction.

FIG. 6 is a view illustrating a cross section of a pixel including a light emitting layer formed by an inkjet printing apparatus illustrated in FIG. 1 by way of example.

FIG. 7 is a view illustrating a cross section, on which ink is discharged from an ink storage part and a head part illustrated as a cross section in FIG. 3 to an ink supply part.

FIG. 8 is a view illustrating side surfaces of an ink storage part, a head part, a pressure applying part, and an ink supply part illustrated in FIG. 1.

FIG. 9 is a cross-sectional view of a pressure applying part and an ink supply part illustrated in FIG. 8.

FIG. 10 is an enlarged view of an opening defined in an ink supply part illustrated in FIG. 9.

FIG. 11 is a view illustrating a cross section, on which the ink illustrated in FIG. 9 is discharged from an ink supply part by a pressure applying part.

FIG. 12 is a view illustrating a process of forming a light emitting layer by using the inkjet printing apparatus illustrated in FIG. 11.

FIGS. 13A to 13E are views illustrating an operation of an inkjet printing apparatus of the disclosure.

FIGS. 14 to 16 are views illustrating cross-sectional configurations of inkjet printing apparatuses according to embodiments of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In the specification, when it is mentioned that a component (or an area, a layer, a part, or the like) is “connected to”, or “coupled to” another component, it means that the former component may be directly connected to, or coupled to the latter component or an intervening component may be disposed between the components.

The same reference numerals denote the same components. Furthermore, in the drawings, thicknesses, ratios, dimensions of the components are exaggerated for an effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms, including technical and scientific terms, used herein have the same meaning as commonly understood by those skilled in the art to which this disclosure belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

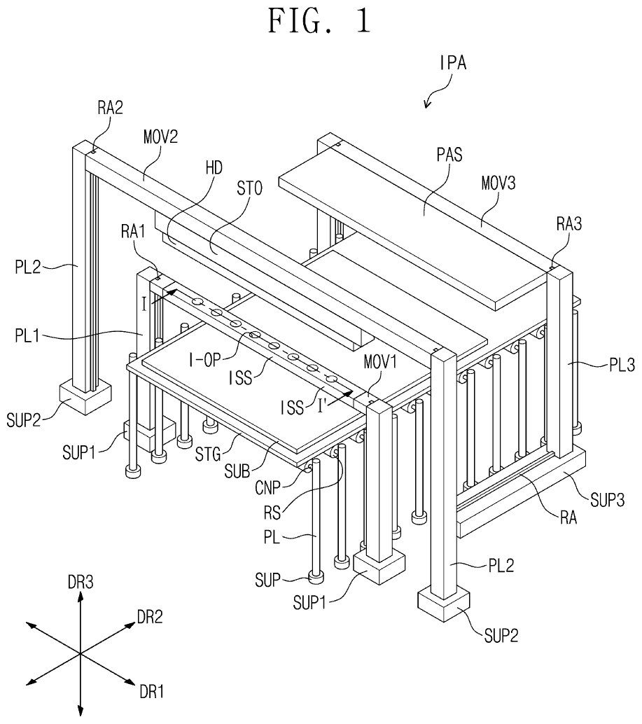

FIG. 1 is a view illustrating a configuration of an inkjet printing apparatus according to an embodiment of the disclosure.

Referring to FIG. 1, an inkjet printing apparatus IPA according to an embodiment of the disclosure may include a stage STG, first, second, and third movement parts MOV1, MOV2, and MOV3, a head part HD, an ink storage part STO, an ink supply part ISS, a pressure applying part PAS, a plurality of rollers RS, a plurality of pillars PL, a plurality of first, second, and third pillars PL1, PL2, and PL3, a plurality of support parts SUP, a plurality of first, second, and third support parts SUP1, SUP2, and SUP3, a plurality of rails RA, a plurality of first, second, and third rails RA, RA1, RA2, and RA3.

The stage STG may have a surface on a plane that is defined by a first direction DR1 and a second direction DR2 that crosses the first direction DR1. Hereinafter, a direction that crosses the plane defined by the first and second directions DR1 and DR2 is defined as a third direction DR3. In the specification, “when viewed on a plane” or “when viewed in a plan view” is defined as a state, in which is viewed in the third direction DR3.

The stage STG may have a rectangular shape having short sides that extend in the first direction DR1 and long sides that extend in the second direction DR2 when viewed on a plane. A substrate SUB that is a target object may be disposed on the stage STG. Although not illustrated, the stage STG may include a plurality of vacuum suction holes for vacuum-suctioning and fixing the substrate SUB thereon. The stage STG may be disposed on the rollers RS.

The support parts SUP may be spaced apart from each other in the first direction DR1, and may be arranged in the second direction DR2. The pillars PL may be spaced apart from each other in the first direction DR1, and may be arranged in the second direction DR2. The pillars PL may extend in the third direction DR3, and may be disposed on the support parts SUP.

The rollers RS may have a cylindrical shape that extends in the first direction DR1. The rollers RS may be rotated or rotatable about a rotation axis that is parallel to the first direction DR1. The rollers RS may rotate clockwise or counterclockwise. The rollers RS may be disposed between the pillars PL that are spaced apart from each other in the first direction DR1. The rollers RS may be disposed adjacent to an upper side of the pillars PL, and may be connected to the pillars PL.

The stage STG may reciprocate in the second direction DR2 as the rollers RS are rotated. As the stage STG is moved, the substrate SUB may reciprocate in the second direction DR2 together with the stage STG.

The first support parts SUP1 may be spaced apart from each other in the first direction DR1. The first pillars PL1 may be spaced apart from each other in the first direction DR1, and may extend in the third direction DR3. The first pillars PL1 may be disposed on the first support parts SUP1, respectively.

The support parts SUP may be disposed on an inner side of the first support parts SUP1. The pillars PL may be disposed on an inner side of the first pillars PL1. The stage STG may be disposed between the first pillars PL1.

The first movement parts MOV1 may be spaced apart from each other in the first direction DR1. The first movement parts MOV1 may be disposed on inner surfaces of the first pillars PL1 that face each other in the first direction DR1 when viewed on a plane.

The first movement parts MOV1 may reciprocate in the third direction DR3 along the first pillars PL1. First rails RA1 may be disposed or defined on inner surfaces of the first pillars PL1 that face each other in the first direction DR1. The first rails RA1 may extend in the third direction DR3. The first rails RA1 may be connected to the inner surfaces of the first pillars PL1. The first movement parts MOV1 may be coupled to (e.g., slidably engaged with) the first rails RA1, and may reciprocate in the third direction DR3 along the first rails RA1.

The ink supply part ISS may extend in the first direction DR1, and may be disposed between the first movement parts MOV1. Accordingly, the first movement parts MOV1 may be disposed between the ink supply part ISS and the first pillars PL1. The ink supply part ISS may be connected to the first movement parts MOV1. As the first movement parts MOV1 reciprocate in the third direction DR3, the ink supply part ISS connected to the first movement parts MOV1 may also reciprocate in the third direction DR3. That is, the ink supply part ISS may reciprocate in the third direction DR3 with the first movement parts MOV1. A plurality of openings I_OP may be defined in the ink supply part ISS.

When viewed on a plane, each of the openings I_OP may have a circular shape. In an embodiment, for example, each of the openings I_OP may have a circular shape, but the shape of the openings I_OP is not limited thereto.

The ink supply part ISS may include metal. The ink supply part ISS may include a glass ceramic having low temperature change and low thermal expansion properties. In an embodiment, for example, the ink supply part ISS may include an inorganic, non-porous lithium aluminum silicon oxide glass-ceramic (e.g., Zerodur®) having a low thermal expansion coefficient.

The ink supply part ISS may be disposed on the substrate SUB as the first movement parts MOV1 are moved, and may supply ink to the substrate SUB. The ink may be provided to the openings I_OP of the ink supply part ISS through the head part HD that will be described later. The ink supply part ISS may provide ink onto the substrate SUB through the openings I_OP.

The second support parts SUP2 may be spaced apart from each other in the first direction DR1. The second pillars PL2 may be spaced apart from each other in the first direction DR1, and may extend in the third direction DR3. The second pillars PL2 may be disposed on the second support parts SUP2, respectively.

The first support parts SUP1 may be disposed on an inner side of the second support parts SUP2. The first pillars PL1 may be disposed on an inner side of the second pillars PL2 when viewed on a plane. Accordingly, the first support parts SUP1 and the first pillars PL1 may be disposed between the second support parts SUP2 and the second pillars PL2.

The second movement part MOV2 may extend in the second direction DR2. The second movement part MOV2 may be disposed between the second pillars PL2 that are spaced apart from each other in the first direction DR1. The second movement part MOV2 may be disposed on the inner surfaces of the second pillars PL2 that face each other in the first direction DR1 when viewed on a plane.

The second movement part MOV2 may reciprocate in the third direction DR3 along the second pillars PL2. Second rails RA2 may be disposed on the inner surfaces of the second pillars PL2 that face each other in the first direction DR1. The second rails RA2 may extend in the third direction DR3. The second rails RA2 may be connected to inner surfaces of the second pillars PL2. The second movement part MOV2 may be coupled to the second rails RA2, and may reciprocate in the third direction DR3 along the second rails RA2.

The ink storage part STO and the head part HD may extend in the first direction DR1, and may be disposed under the second movement part MOV2. The head part HD may be disposed under the ink storage part STO. The head part HD may be connected to the ink storage part STO. The ink storage part STO may be disposed under the second movement part MOV2, and may be connected to the second movement part MOV2. As the second movement part MOV2 reciprocates in the third direction DR3, the head part HD and the ink storage part STO may reciprocate in the third direction DR3.

Ink may be stored in the ink storage part STO. The ink may include an organic material for forming the organic light emitting layer.

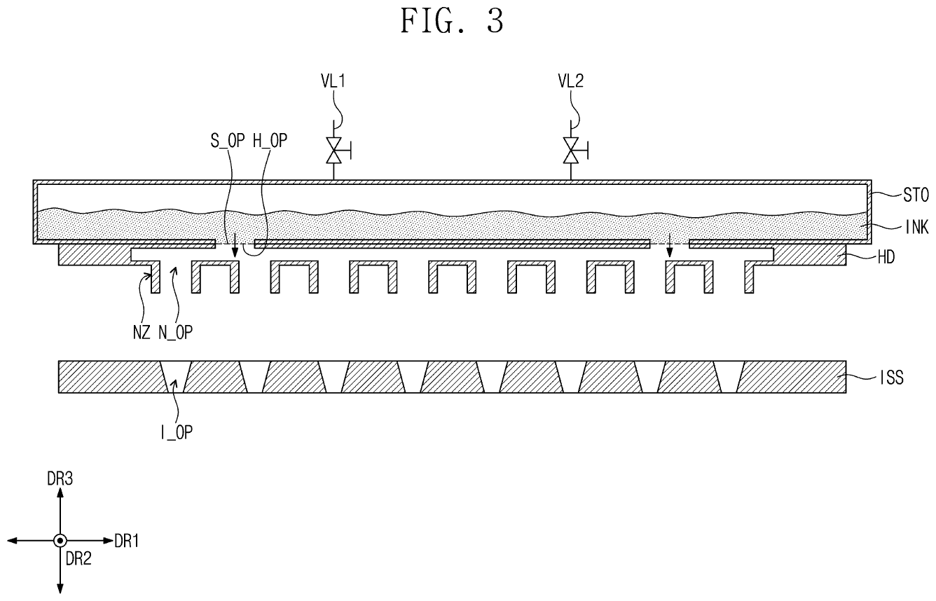

The ink stored in the ink storage part STO may be provided to the head part HD. The head part HD may discharge the ink provided thereto. The head part HD may be moved in the third direction DR3 as the second movement part MOV2 is moved, and may be disposed above the ink supply part ISS. The head part HD may include a plurality of nozzles (hereinafter, illustrated in FIG. 3) that discharges the ink. In an embodiment, for example, the head part HD may be disposed above the ink supply part ISS, and may discharge the ink through nozzles to the openings I_OP of the ink supply part ISS.

The third support parts SUP3 may be spaced apart from each other in the first direction DR1. Although one third support part SUP3 is illustrated in a perspective view, a third support part SUP3 may be further disposed on substantially the left side thereof. The third support parts SUP3 may extend in the second direction DR2. The third support parts SUP3 may be adjacent to the first support parts SUP1 in the third direction DR3.

The third pillars PL3 may be disposed on the third support parts SUP3, respectively. The third pillars PL3 may extend in the third direction DR3. The stage STG may be disposed between the third pillars PL3. The third pillars PL3 may reciprocate in the second direction DR2 along upper surfaces of the third support parts SUP3. Rails RA that extend in the second direction DR2 may be disposed on upper surfaces of the third support parts SUP3. The third pillars PL3 may be coupled to (e.g., slidably engaged with) rails RA, and may reciprocate in the second direction DR2 along the rails RA.

The third movement part MOV3 may extend in the first direction DR1, and may be disposed between the third pillars PL3 that are spaced apart from each other in the first direction DR1. The third movement part MOV3 may reciprocate in the third direction DR3 along the third pillars PL3. Third rails RA3 may be disposed on the inner surfaces of the third pillars PL3 that face each other in the first direction DR1. The third rails RA3 may extend in the third direction DR3. The third rails RA3 may be connected to inner surfaces of the third pillars PL3. The third movement part MOV3 may be coupled to (e.g., slidably engaged with) the third rails RA3, and may reciprocate in the third direction DR3.

The pressure applying part PAS may be connected to one side of the third movement part MOV3, which faces the ink supply part ISS. The third movement part MOV3 may have a rectangular shape having long sides that extend in the first direction DR1 and short sides that extend in the second direction DR2. As the third pillars PL3 is moved in the second direction DR2, and the third movement part MOV3 is moved in the third direction DR3, the pressure applying part PAS may reciprocate in the second direction DR2, and may reciprocate in the third direction DR3.

In an embodiment, the pressure applying part PAS may be moved in the second direction DR2 by the third pillars PL3, and may be disposed between the head part HD and the ink supply part ISS. In such an embodiment, the pressure applying part PAS may be moved in the third direction DR3 by the third movement part MOV3, and may be disposed on the upper surface of the ink supply part ISS to apply a pressure to the ink supply part ISS. The operation will be described in detail below.

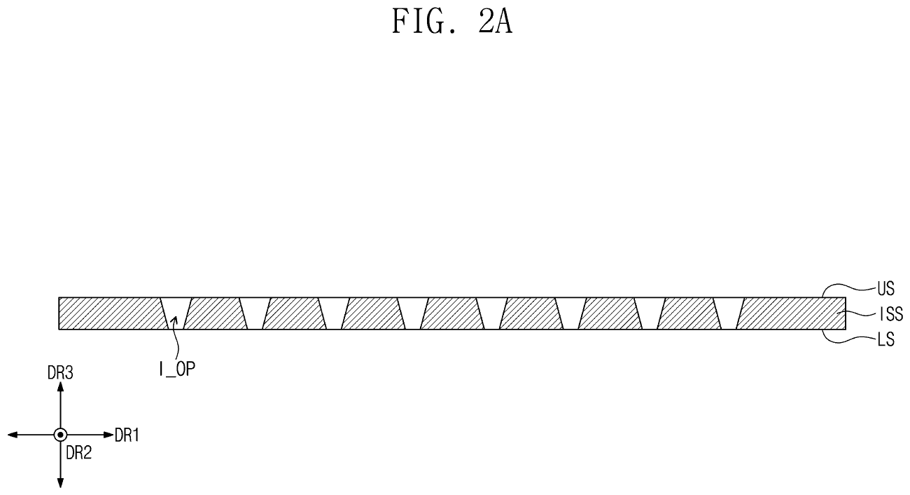

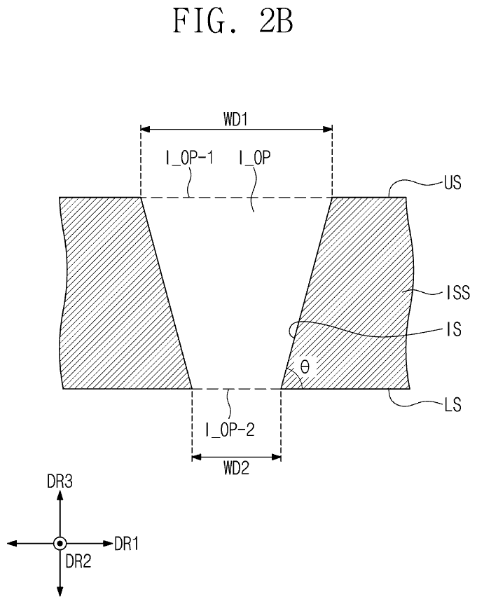

FIG. 2A is a cross-sectional view of an ink supply part taken along line I-l′ illustrated in FIG. 1. FIG. 2B is an enlarged view of any one opening illustrated in FIG. 2.

Referring to FIG. 2A, the plurality of openings I_OP may be defined in the ink supply part ISS. Although eight openings I_OP are illustrated in FIG. 2A by way of example, the number of the openings I_OP is not limited thereto. The openings I_OP may be arranged in the first direction DR1. The openings I_OP may be arranged to be spaced apart from each other at equal intervals in the first direction DR1.

A width of the opening I_OP in a horizontal direction (e.g., the first direction DR1 or the second direction DR2) that is parallel to the upper surface US of the ink supply part ISS may gradually decrease in a downward direction, that is, as going downward.

Referring to FIG. 2B, a width WD1 of an uppermost side I_OP-1 of the opening I_OP may be greater than a width WD2 of a lowermost side I_OP-2 of the opening I_OP. In an embodiment, for example, the width WD2 of the lowermost side I_OP-2 of the opening I_OP may be in a range of about 1 micrometer to about 2 micrometers. The uppermost side I_OP-1 of the opening I_OP may overlap the upper surface US, and the lowermost side I_OP-2 of the opening I_OP may overlap a lower surface LS.

An inner surface IS of the ink supply part ISS, which defines the opening I_OP, may have an inclined surface. The inner surface IS of the ink supply part ISS may form an acute angle with the lower surface LS of the ink supply part ISS. Furthermore, the inner surface IS of the ink supply part ISS may form an obtuse angle with the upper surface US of the ink supply part ISS. The inner surface IS of the ink supply part ISS may form an obtuse angle with the lower surface of the ink supply part ISS, e.g., an angle in a range of about 50 degrees to about 70 degrees.

FIG. 3 is a view illustrating cross sections of an ink storage part, a head part, and an ink supply part illustrated in FIG. 1 by way of example.

Particularly, a cross section illustrated in FIG. 3 is a cross section that is viewed in the second direction DR2, and may be a cross-sectional view corresponding to FIG. 2A.

Referring to FIG. 3, in an embodiment, the ink storage part STO may accommodate ink INK. A first valve VL1 may be connected to an upper portion of the ink storage part STO. The ink INK may be supplied to the ink storage part STO through the first valve VL1. In an embodiment, for example, a sensor (not illustrated) may be disposed in the ink storage part STO, and the sensor may measure a height of the ink INK that is accommodated in the ink storage part STO. The first valve VL1 may be opened and closed depending on the measured height of the ink INK, and thus, the ink INK may be supplied to the ink storage part STO.

A second valve VL2 may be spaced apart from the first valve VL1, and may be connected to an upper portion of the ink storage part STO. The second valve VL2 may provide a negative pressure to the ink storage part STO. The negative pressure may be defined as a pressure from an interior of the ink storage part STO toward the outside of the ink storage part STO. When the second valve VL2 is opened, a negative pressure may be provided to the ink storage part STO.

When the discharge of the ink INK from the head part HD is to be stopped, the second valve VL2 may be opened such that the ink INK is no longer discharged, and thus a negative pressure may be provided to the ink storage part STO. The negative pressure may be a force that pulls the ink INK upward such that the height of the ink INK is not lowered any more. The ink INK is not discharged from the head part HD by the negative pressure, and the height of the ink INK stored in the ink storage part STO may be maintained constant. When the ink INK is discharged through the head part HD, the second valve VL2 may be closed.

A plurality of openings S_OP may be defined under the ink storage part STO. Although two openings S_OP are illustrated in FIG. 3 by way of example, the number of openings S_OP defined in the ink storage part STO is not limited thereto.

The head part HD may be connected to a lower portion of the ink storage part STO. A plurality of openings H_OP may be defined at an upper portion of the head part HD, and may overlap the openings S_OP defined in the ink storage part STO. In an embodiment, for example, two openings H_OP are defined in the head part HD, but the number thereof is not limited thereto.

The head part HD may include a plurality of nozzles NZ that extend downward. Although eight nozzles NZ are illustrated by way of example, the number of the nozzles NZ is not limited thereto. Nozzle holes N_OP that extend in the third direction DR3 may be defined in the nozzles NZ, respectively.

The ink supply part ISS may be disposed under the head part HD. The openings I_OP defined in the ink supply part ISS may overlap the nozzles NZ, respectively. A width of a lower side of each of the openings I_OP may be smaller than a width of each of the nozzle holes N_OP.

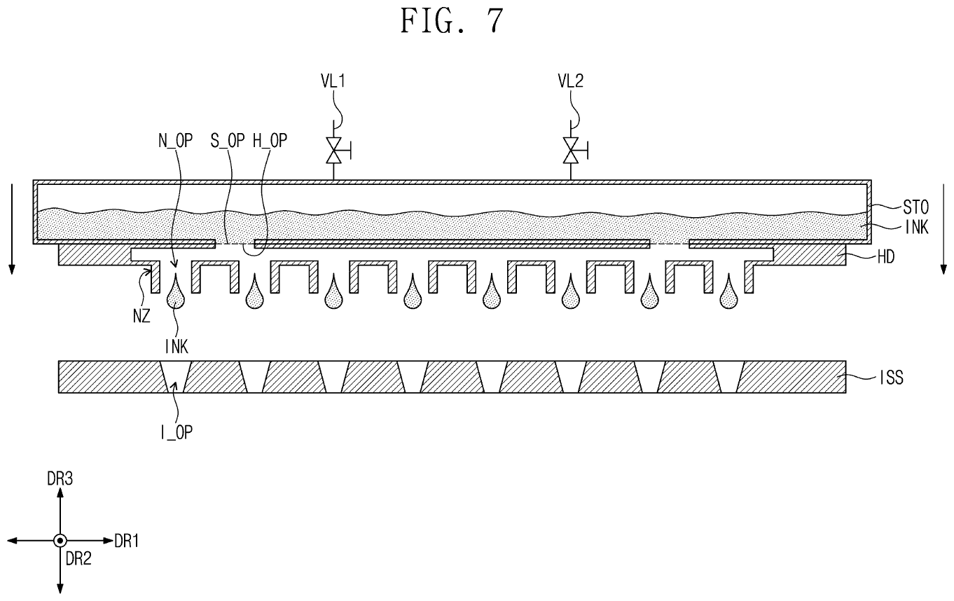

The ink INK may be discharged through the nozzles NZ, and may be provided to the opening I_OP of the ink supply part ISS. The operation will be illustrated in FIG. 7 below.

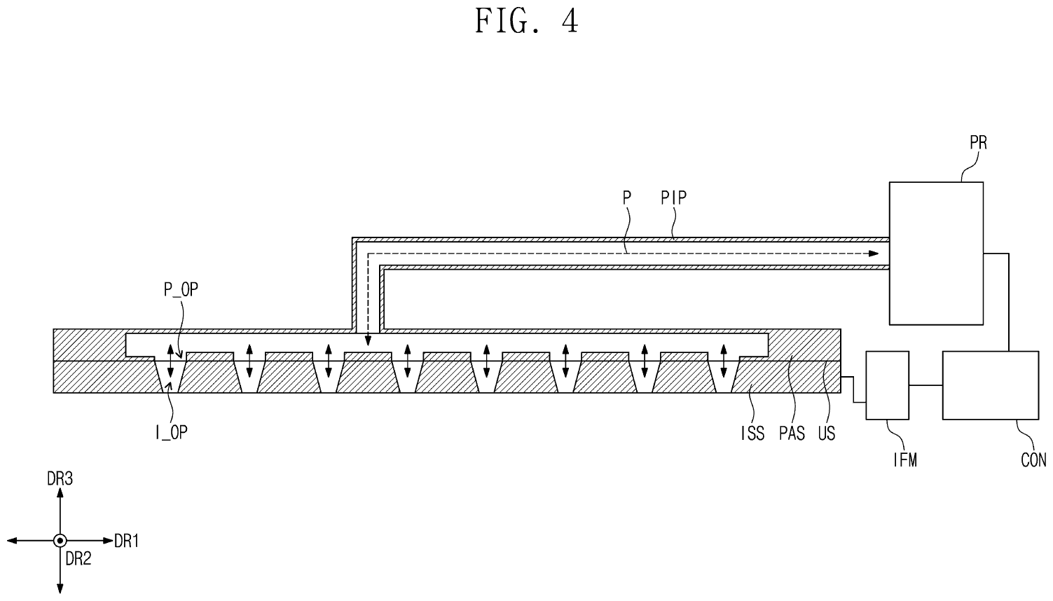

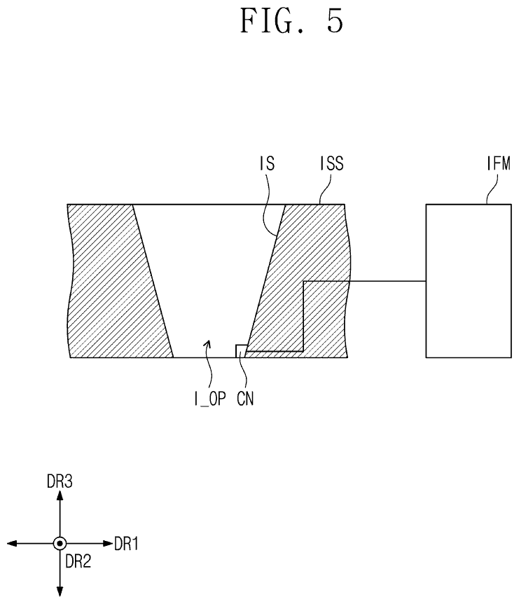

FIG. 4 is a view illustrating a cross section of a pressure applying part and an ink supply part illustrated in FIG. 1 by way of example. FIG. 5 is a cross-sectional view of an opening of an ink supply part illustrated in FIG. 4, when viewed from a first direction.

Particularly, a cross section illustrated in FIG. 4 is a cross section that is viewed in the second direction DR2, and is a cross-sectional view corresponding to FIG. 2A.

Referring to FIG. 4, in an embodiment, the inkjet printing apparatus IPA may further include a pneumatic pressure regulator PR, a pipe PIP, an ink flow rate measuring part IFM, and a controller CON. In an embodiment, for example, a pneumatic pressure regulator PR, a pipe PIP, an ink flow rate measuring part IFM, and a controller CON illustrated in FIG. 4 are omitted from FIG. 1 for convenience of illustration.

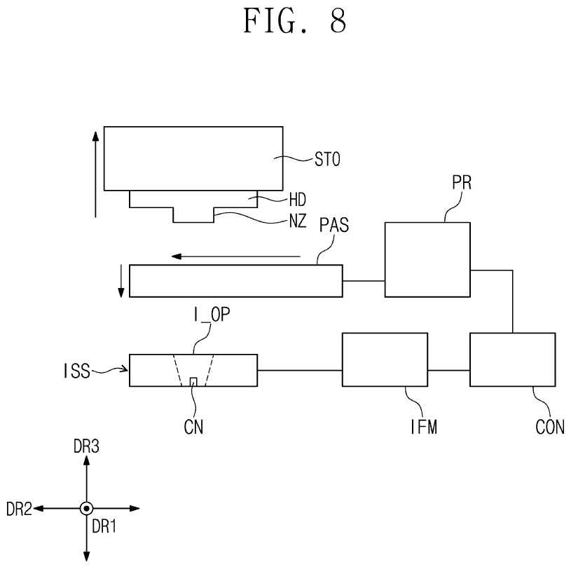

The pneumatic pressure regulator PR, the pipe PIP, the ink flow rate measuring part IFM, and the controller CON may be connected to the pressure applying part PAS. The pressure applying part PAS may be disposed to contact an upper surface US of the ink supply part ISS. A configuration, in which the pressure applying part PAS is moved and contacts the upper surface US of the ink supply part ISS, will be illustrated in FIG. 8 below.

A plurality of openings P_OP may be defined under the pressure applying part PAS. In an embodiment, for example, eight openings P_OP are illustrated, but the number of openings P_OP is not limited thereto. The openings P_OP may overlap the openings I_OP of the ink supply part ISS, respectively.

The pressure applying part PAS may be connected to the pneumatic pressure regulator PR through the pipe PIP. The pneumatic pressure regulator PR may be supplied with compressed air from a compressor (not illustrated). The pneumatic pressure regulator PR may control the supplied compressed air to air of a preset pressure. The pneumatic pressure regulator PR may provide the air, the pressure of which is controlled, to the pressure applying part PAS through the pipe PIP.

The pneumatic pressure regulator PR may provide a pressure (P) to the pressure applying part PAS. The pressure (P) may include a negative pressure that is a pressure from the interior of the pressure applying part PAS to the outside of the pressure applying part PAS, and a positive pressure that is a pressure from the outside of the pressure applying part PAS to the interior of the pressure applying part PAS. Hereinafter, the pressure (P) applied from the pressure applying part PAS to the ink supply part ISS to discharge the ink INK from the opening I_OP may be defined as a positive pressure, and the pressure (P) applied from the pressure applying part PAS to the ink supply part ISS to allow the ink INK not to be discharged from the opening I_OP may be defined as a negative pressure.

The pressure applying part PAS may apply the pressure (P) to the ink supply part ISS. The pressure applying part PAS may apply the pressure (P) to the openings I_OP through the openings P_OP. In an embodiment, for example, the pressure applying part PAS may apply pressures (P) to the openings I_OP, respectively.

Referring to FIG. 5, an ink flow rate measuring part IFM may be disposed on a side surface of the ink supply part ISS, and may be connected to the ink supply part ISS. The ink flow rate measuring part IFM may be connected to a flow rate measuring sensor CN disposed on a lower portion of the inner surface IS defining the opening I_OP, and may measure a flow rate of the ink INK discharged from a lower portion of the opening I_OP. For convenience of illustration and description, the flow rate measuring sensor CN is omitted from FIG. 4A, and the ink flow rate measuring part IFM is illustrated in a state of being connected to a side surface of the ink supply part ISS.

Referring to FIG. 4, the ink flow rate measuring part IFM may measure an average flow rate of the ink INK measured in the openings I_OP.

The ink flow rate measuring part IFM and the pneumatic pressure regulator PR may be connected to the controller CON. The controller CON may control an operation of the pneumatic pressure regulator PR with the flow rate of the ink INK measured in the ink flow rate measuring part IFM. The controller CON may control the pressure applying part PAS such that the pressures (P) applied to each of the openings I_OP is controlled depending on the flow rate of the ink INK.

The controller CON may compare the flow rate of the ink INK with a target flow rate to calculate an amount of the ink INK discharged from the opening I_OP. The controller CON may control an operation of the pneumatic pressure regulator PR depending on the calculated amount of the ink INK.

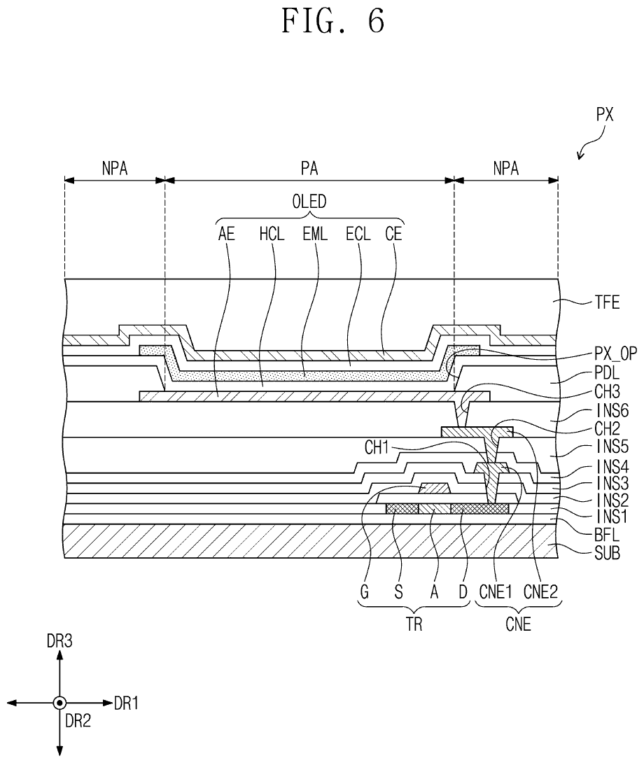

FIG. 6 is a view illustrating a cross section of a pixel including a light emitting layer formed by an inkjet printing apparatus illustrated in FIG. 1 by way of example.

Referring to FIG. 6, in an embodiment, the pixel PX may include a transistor TR, and a light emitting element OLED that is connected to the transistor TR. Although one pixel PX disposed on a substrate SUB is illustrated in FIG. 6 for convenience of illustration, a plurality of pixels PX may be disposed on the substrate SUB.

The light emitting element OLED may include a first electrode AE, a second electrode CE, a hole control layer HCL, an electronic control layer ECL, and a light emitting layer EML. The first electrode AE may be an anode electrode, and the second electrode CE may be a cathode electrode.

The transistor TR and the light emitting element OLED may be disposed on the substrate SUB. A planar area of the substrate SUB may be divided into a light emitting part PA and a non-light emitting part NPA around the light emitting part PA when viewed on a plane. The light emitting element OLED may be disposed on the light emitting part PA.

The substrate SUB may include a glass substrate or a flexible plastic substrate. A buffer layer BFL may be disposed on the substrate SUB, and the buffer layer BFL may be an inorganic layer.

Semiconductor patterns S, A, and D may be disposed on the buffer layer BFL. The semiconductor patterns S, A, and D may include polysilicon. However, the disclosure is not limited thereto, and the semiconductor patterns S, A, and D may include amorphous silicon or metal oxide.

The semiconductor patterns S, A, and D may be doped with an N-type dopant or a P-type dopant. The semiconductor pattern may include a high-doped area and a low-doped area. A conductivity of the high-doped area is greater than that of the low-doped area, and may substantially serve as a source electrode and a drain electrode of the transistor TR. The low-doped area may substantially correspond to an active (or channel) of the transistor.

The source S, the active A, and the drain D of the transistor TR may be formed from the semiconductor patterns S, A, and D. A first insulation layer INS1 may be disposed on the semiconductor patterns S, A, and D. A gate G of the transistor TR may be disposed on the first insulation layer INS1. A second insulation layer INS2 may be disposed on the gate G. A third insulation layer INS3 may be disposed on the second insulation layer INS2.

A connection electrode CNE may be disposed between the transistor TR and the light emitting element OLED, and may connect the transistor TR and the light emitting element OLED. The connection electrode CNE may include a first connection electrode CNE1 and a second connection electrode CNE2.

The first connection electrode CNE1 may be disposed on the third insulation layer INS3, and may be connected to the drain D through first contact holes CH1 defined in the first to third insulation layers INS1 to INS3. A fourth insulation layer INS4 may be disposed on the first connection electrode CNE1. A fifth insulation layer INS5 may be disposed on the fourth insulation layer INS4.

The second connection electrode CNE2 may be disposed on the fifth insulation layer INS5. The second connection electrode CNE2 may be connected to the first connection electrode CNE1 through a second contact hole CH2 defined in the fifth insulation layer INS5. A sixth insulation layer INS6 may be disposed on the second connection electrode CNE2. The first to sixth insulation layer INS1 to INS6 may be an inorganic layer or an organic layer.

A first electrode AE may be disposed on the sixth insulation layer INS6. The first electrode AE may be connected to the second connection electrode CNE2 through a third contact hole CH3 defined in the sixth insulation layer INS6. A pixel definition layer PDL that exposes a specific portion of the first electrode AE may be disposed on the first electrode AE and the sixth insulation layer INS6. In the pixel definition layer PDL, an opening PX_OP for exposing a specific portion of the first electrode AE may be defined.

The hole control layer HCL may be disposed on the first electrode AE and the pixel definition layer PDL. The hole control layer HCL may be disposed in common on the light emitting part PA and the non-light emitting part NPA. The hole control layer HCL may include a hole transport layer and a hole injection layer.

The light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate any one of red, green, and blue light.

The electronic control layer ECL may be disposed on the light emitting layer EML and the hole control layer HCL. The electronic control layer ECL may be disposed in common on the light emitting part PA and the non-light emitting part NPA. The electronic control layer ECL may include an electron transport layer and an electron injection layer.

The second electrode CE may be disposed on the electronic control layer ECL. The second electrode CE may be disposed in common on the pixels PX.

A thin film encapsulation layer TFE may be disposed on the light emitting element OLED. The thin film encapsulation layer TFE may be disposed on the second electrode CE to cover the pixel PX. The thin film encapsulation layer TFE may include at least two inorganic layers and an organic layer between the inorganic layers. The inorganic layer may protect the pixel PX from moisture/oxygen. The organic layer may protect the pixel PX from foreign substances, such as dust particles.

A first voltage may be applied to the first electrode AE through the transistor TR, and a second voltage having a level lower than the first voltage may be applied to the second electrode CE. Holes and electrons that are injected into the light emitting layer EML are coupled to form excitons, and the light emitting element OLED may emit light while the excitons are transitioned to a ground state.

FIG. 7 is a view illustrating a cross section, on which ink is discharged from an ink storage part and a head part illustrated as a cross section in FIG. 3 to an ink supply part.

Referring to FIG. 7, in an embodiment, the ink storage part STO and the head part HD may be moved in a downward direction in the third direction DR3, and may be disposed adjacent to the ink supply part ISS. In an embodiment, for example, as the second movement part MOV2 moves in a downward direction, the ink storage part STO and the head part HD may be move in a downward direction.

The ink storage part STO and the head part HD may be spaced apart from the ink supply part ISS by a specific interval. In an embodiment, for example, a lower portion of the nozzle NZ and an upper portion of the ink supply part ISS may be spaced apart from each other by less than about 1 millimeter.

The first valve VL1 connected to the ink storage part STO may be opened, and thus, the ink INK stored in the ink storage part STO may be provided to the head part HD. The ink INK stored in the ink storage part STO may be provided to the head part HD through the opening S_OP and H_OP.

The ink INK provided to the head part HD may be discharged through nozzle holes N_OP defined in a plurality of nozzles NZ. The nozzles NZ may discharge the ink INK to the openings I_OP through the nozzle holes N_OP. The ink INK may be provided to the openings I_OP, and may be accommodated in the openings I_OP.

When the discharge of the ink INK from the nozzles NZ is to be stopped, the second valve VL2 may be opened to provide a negative pressure to the ink storage part STO.

FIG. 8 is a view illustrating side surfaces of an ink storage part, a head part, a pressure applying part, and an ink supply part illustrated in FIG. 1.

In an embodiment, for example, a side surface illustrated in FIG. 8 may be a side surface viewed from the first direction DR1.

Referring to FIG. 8, in an embodiment, after the head part HD supplies the ink to the ink supply part ISS through the nozzle NZ, the ink storage part STO and the head part HD may be move in an upward direction in the third direction DR3.

Next, the pressure applying part PAS may be moved in the second direction DR2, and may be disposed between the head part HD and the ink supply part ISS. In an embodiment, for example, as the third pillar PL3 is moved in the second direction DR2, the pressure applying part PAS may be moved in the second direction DR2.

The pressure applying part PAS may be moved in a downward direction in the third direction DR, and may be disposed above the ink supply part ISS. In an embodiment, for example, as the third movement part is moved in a downward direction, the pressure applying part PAS may be moved in a downward direction. In such an embodiment, as illustrated in FIG. 4, a lower portion of the pressure applying part PAS may contact an upper portion of the ink supply part ISS.

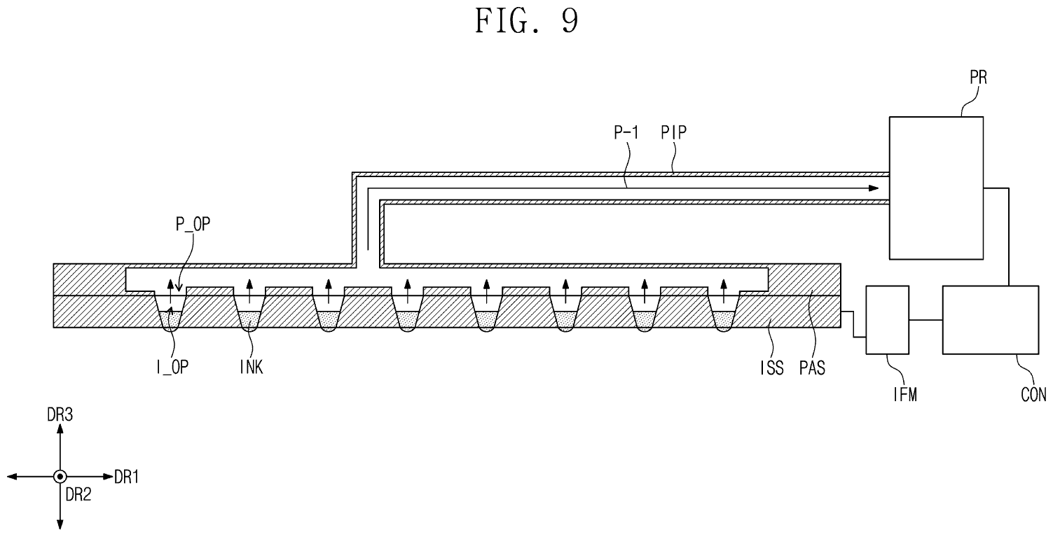

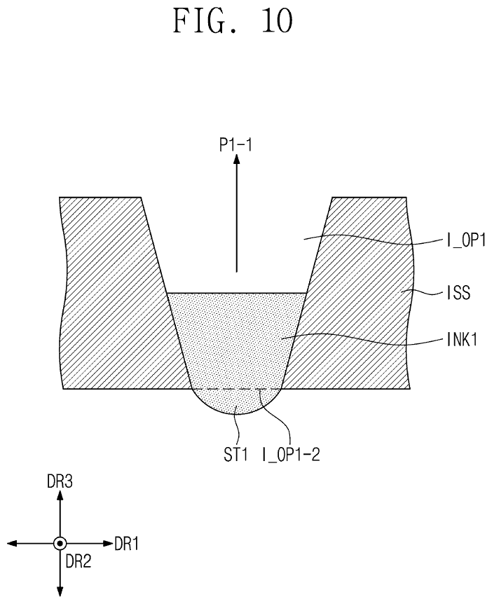

FIG. 9 is a cross-sectional view of a pressure applying part and an ink supply part illustrated in FIG. 8.

Particularly, FIG. 9 is illustrated as a cross section corresponding to FIG. 4, and illustrates a state, in which the ink is not discharged by the pressure applying part PAS in the opening I_OP provided with the ink INK.

The pipe PIP may be connected to an upper portion of the pressure applying part PAS, and the pressure applying part PAS may be connected to the pneumatic pressure regulator PR through the pipe PIP. The pneumatic pressure regulator PR may provide a negative pressure P-1 to the pressure applying part PAS. The negative pressure P-1 may be defined as the pressure from an interior of the pressure applying part PAS to the outside of the pressure applying part PAS.

The pressure applying part PAS may apply the negative pressure P-1 to the openings I_OP. The ink INK may not be discharged from the openings I_OP due to the negative pressure P-1.

Before the ink INK are discharged to the substrate SUB, the negative pressure P-1 may be applied to the openings I_OP through the pressure applying part PAS such that the ink INK may not be discharged. Depending on a surface tension of the ink INK, the ink INK may be in a state, in which the ink INK is convex downward.

FIG. 10 is an enlarged view of an opening defined in an ink supply part illustrated in FIG. 9.

Referring to FIG. 10, in an embodiment, a negative pressure P1-1 may be applied to the first opening I_OP1 in the third direction DR3. The negative pressure P1-1 may be defined as a pressure from an interior of the ink supply part ISS toward the outside of the ink supply part ISS (e.g., the pressure applying part).

The ink INK 1 may not be discharged from the first opening I_OP1 due to the negative pressure P1-1.

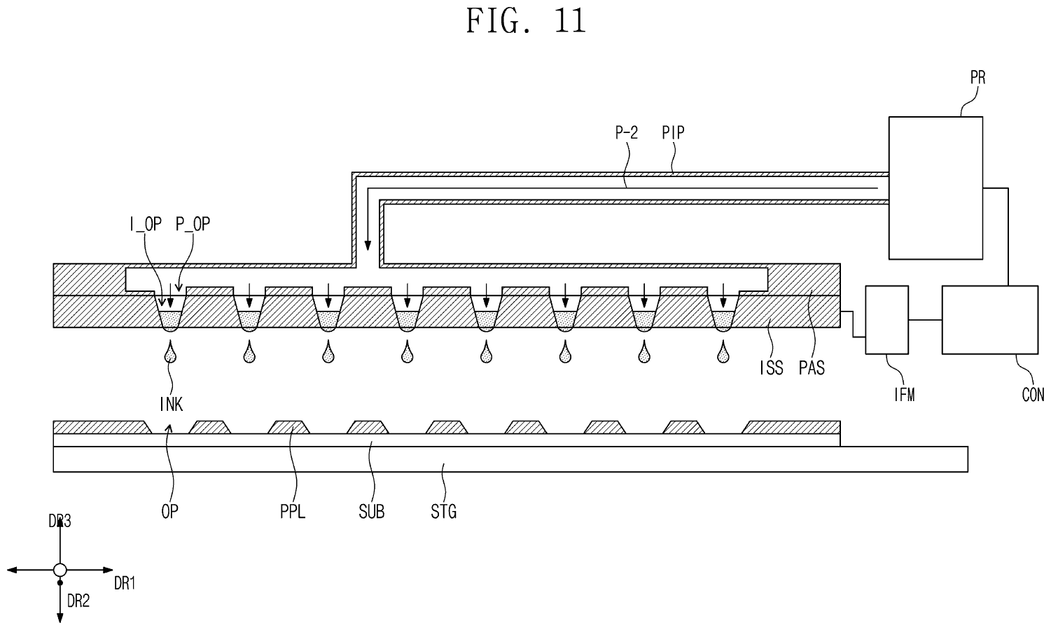

FIG. 11 is a view illustrating a cross section, on which the ink illustrated in FIG. 9 is discharged from an ink supply part by a pressure applying part.

Referring to FIG. 11, a substrate SUB may be disposed on a stage STG, and a pixel definition layer PDL, in which a pixel opening OP is defined, may be disposed on a substrate SUB. In an embodiment, for example, components between the substrate SUB and the pixel definition layer PDL in FIG. 11, and the first electrode AE and the hole layer are omitted.

The pneumatic pressure regulator PR may provide a pressure P-2 to the pressure applying part PAS through the pipe PIP. The pressure P-2 may be defined as a positive pressure from the outside of the pressure applying part PAS toward an interior of the pressure applying part PAS. The pressure P-2 may be applied to the openings I_OP through the pressure applying part PAS. Accordingly, the pressure P-2 may be applied to the ink INK disposed in the openings I_OP. The ink INK may be discharged toward the substrate SUB by the pressure P-2.

The controller CON may control the pressure P-2 applied from the pneumatic pressure regulator PR to the pressure applying part PAS depending on the flow rate of the ink INK, which is measured in the ink flow rate measuring part IFM. The controller CON may compare the flow rate of the ink INK with a target flow rate to determine an amount of ink INK discharged from the openings I_OP.

In an embodiment, for example, when the measured flow rate of the ink INK is greater than the target flow rate, the controller CON may determine that the amount of the ink discharged from the opening I_OP is greater than a reference amount. When it is determined that the amount of the ink discharged from the opening I_OP is greater than the reference amount, the controller CON may control the pneumatic pressure regulator PR in a way such that the pressure P-2 applied from the pneumatic pressure regulator PR becomes smaller. When the pressure P-2 increases, the flow rate of the ink INK increases, and thus an amount of the discharged ink INK may increase. The reference amount may be defined as the amount of the discharged ink INK, which is set by the user, and the target flow rate may be defined as a flow rate corresponding to the reference amount.

When the measured flow rate of the ink INK is smaller than the target flow rate, the controller CON may determine that the amount of the ink discharged from the opening I_OP is smaller than a reference amount. When it is determined that the amount of the ink discharged from the opening I_OP is smaller than the reference amount, the controller CON may control the pneumatic pressure regulator PR in a way such that the pressure P-2 applied from the pneumatic pressure regulator PR becomes higher.

Accordingly, the pressure applying part PAS may precisely control the pressure P-2 applied to the ink supply part ISS depending on the flow rate of the ink discharged from the opening I_OP. The amount of the ink discharged through the opening I_OP may be smaller than the amount of the ink discharged from the above-described nozzles NZ.

The ink INK discharged through the openings I_OP may be provided to the pixel openings OP defined in the pixel definition layer PDL disposed on the substrate SUB. A width of lower sides of the openings I_OP defined on a lower surface of the ink supply part ISS may be smaller than a width of the pixel openings OP.

Accordingly, the pressure applying part PAS may discharge a smaller amount of ink from the openings I_OP to the pixel openings OP.

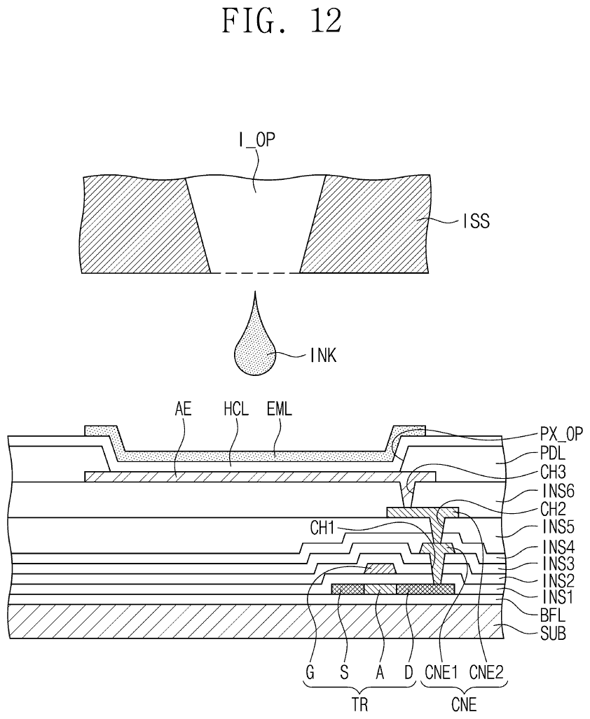

FIG. 12 is a view illustrating a process of forming a light emitting layer by using the inkjet printing apparatus illustrated in FIG. 11.

Referring to FIG. 12, in an embodiment, an ink supply part ISS may be disposed above a substrate SUB. A hole control layer HCL may be disposed on the first electrode AE, and the ink supply part ISS may be used to form a light emitting layer EML on the hole control layer HCL. The ink INK discharged from the ink supply part ISS may be provided onto the hole control layer HCL to form the light emitting layer EML.

In FIG. 12, forming only one light emitting layer EML on the substrate SUB is shown for convenience of illustration, but in an embodiment, a plurality of light emitting layers EML may be simultaneously formed on the substrate SUB.

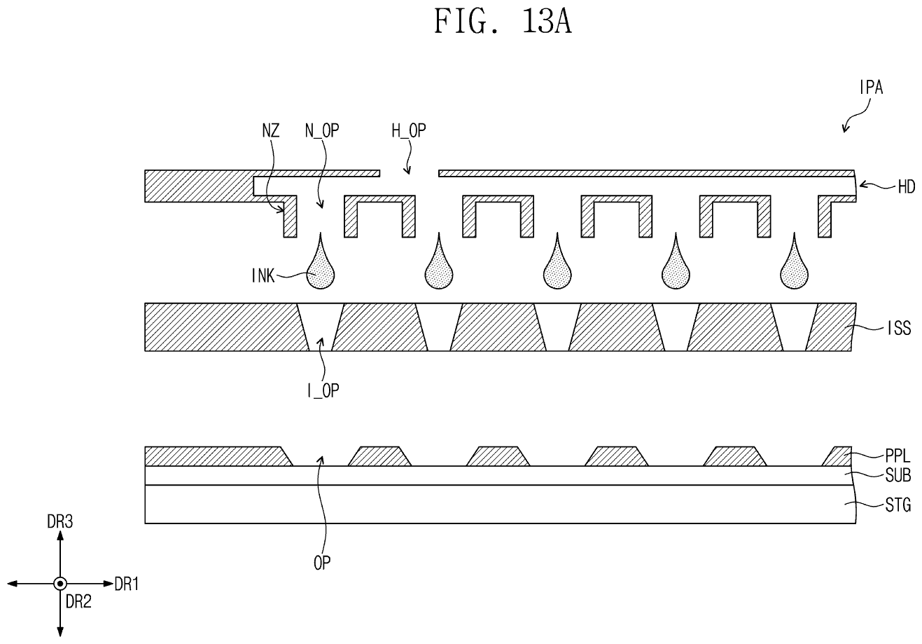

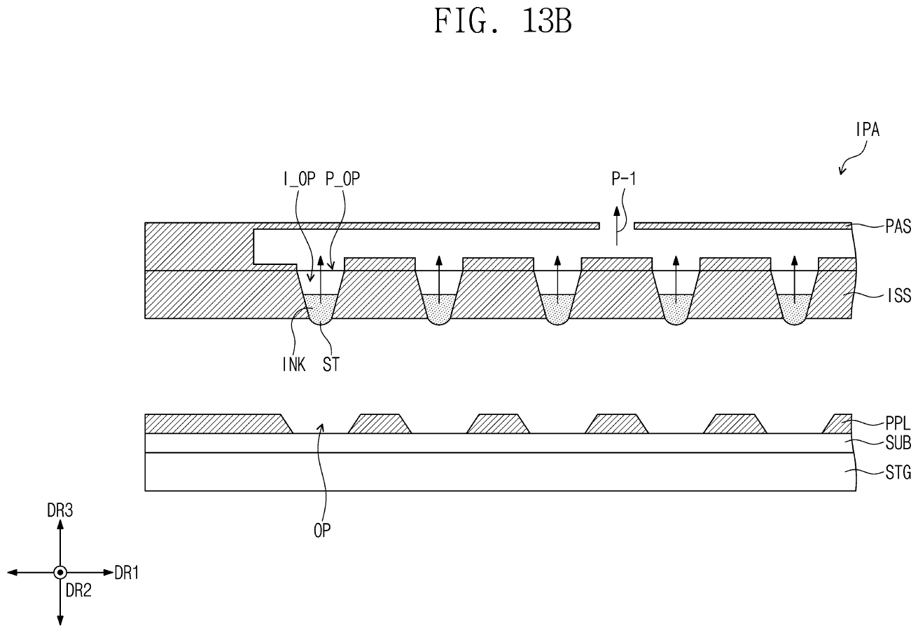

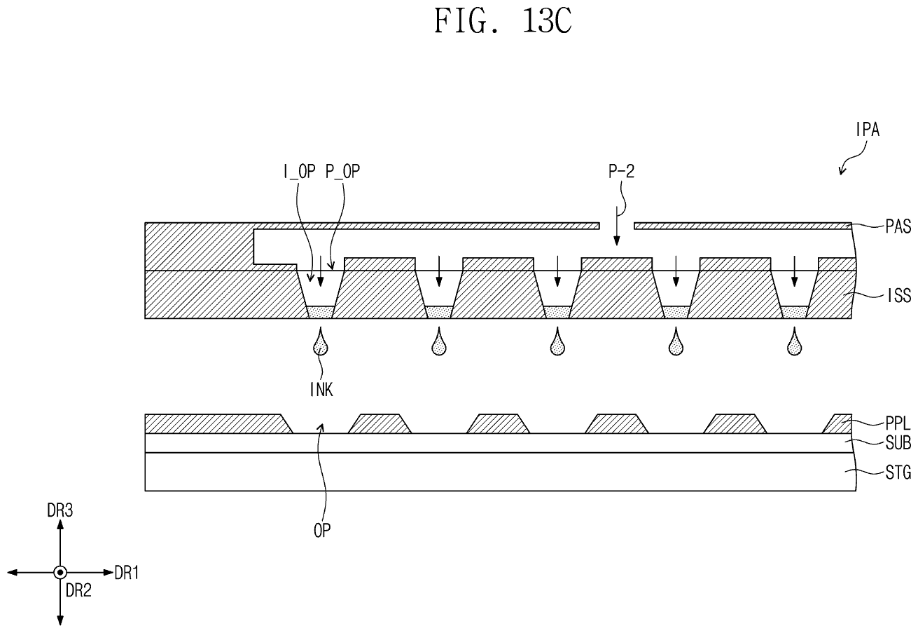

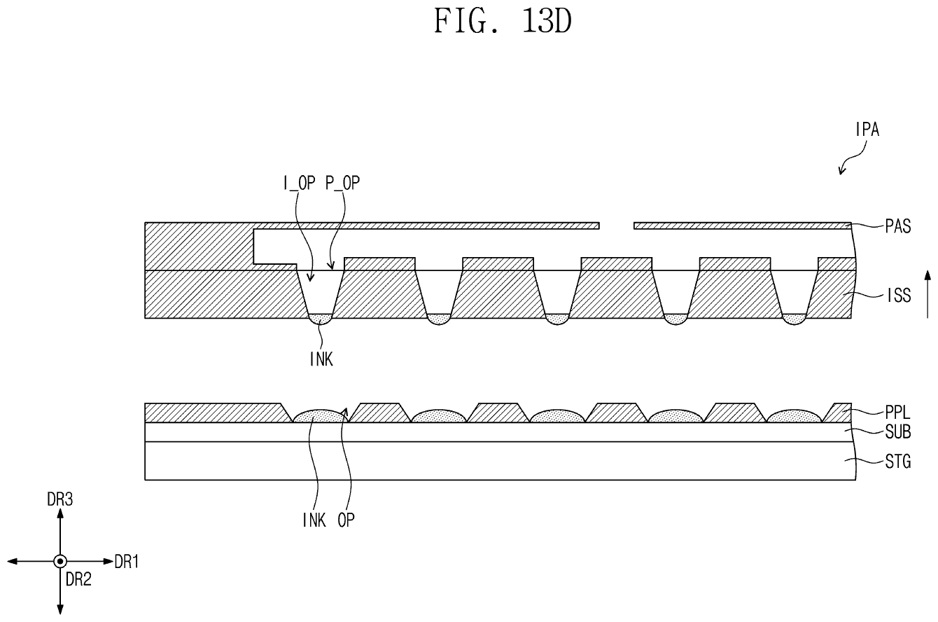

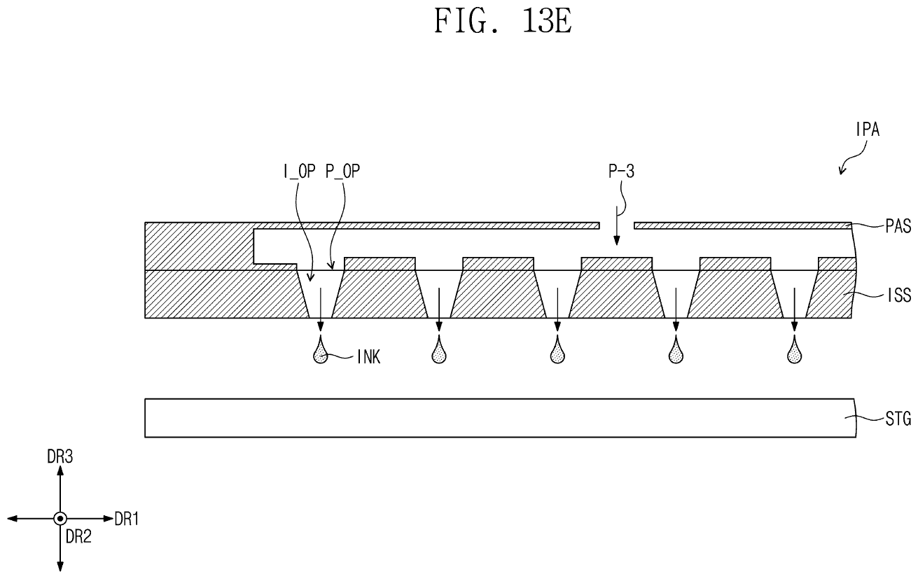

FIGS. 13A to 13E are views illustrating an operation of an inkjet printing apparatus of the disclosure. FIGS. 13A to 13E may be cross-sections viewed in the first direction DR1. A cross section of an inkjet printing apparatus IPA is illustrated in FIGS. 13A to 13E. For convenience of illustration and description, the inkjet printing apparatus IPA is enlarged and a portion thereof is briefly illustrated.

Hereinafter, the inkjet printing operation will be briefly described with reference to the above-described inkjet printing apparatus.

Referring to FIG. 13A, in an embodiment, a head part HD including nozzles NZ may be disposed on an ink supply part ISS, in which opening I_OPs are defined. The head part HD may discharge ink INK from the nozzles NZ to the ink supply part ISS. The head part HD may provide the ink INK to the openings I_OP defined in the ink supply part ISS.

Referring to FIG. 13B, a pressure applying part PAS may be disposed on the ink supply part ISS in an upward direction of the head part HD. A pressure applying part PAS may contact an upper portion of the ink supply part ISS. The pressure applying part PAS may apply a negative pressure P-1 to the ink supply part ISS. In an embodiment, for example, before the ink INK is discharged to the substrate SUB, the negative pressure P-1 may be applied to the openings I_OP through the pressure applying part PAS such that the ink INK may not be discharged.

Referring to FIG. 13C, the ink supply part ISS may be disposed above a substrate SUB. The pressure applying part PAS may apply a pressure P-2 (e.g., a positive pressure) to the ink supply part ISS. The ink supply part ISS may discharge the ink INK due to the pressure.

As the stage STG is moved, the substrate SUB is moved, and the substrate SUB is moved, the ink may be provided to the pixel openings OP. The pressure applying part PAS and the ink supply part ISS may repeat a process of discharging the ink INK until the ink stored in the ink supply part ISS is exhausted. As illustrated in FIG. 1, a substrate SUB may be disposed on the rollers RS, and may reciprocate in the second direction DR2. When the ink INK is discharged once from the openings I_OP, the substrate SUB may be moved in the second direction DR2 by the rollers RS.

An amount of the ink INK discharged once from the opening I_OP may be smaller than an amount of the ink INK discharged from the nozzles NZ.

Referring to FIG. 13D, after the ink INK is discharged from the openings I_OP toward the substrate SUB N times, the ink INK may remain in the ink supply part ISS. An amount of the remaining ink INK may be insufficient to form a light emitting layer.

In an embodiment, for example, the remaining ink INK exists in all the openings I_OPs, but is not limited thereto, and the remaining ink INK may exist only in some opening I_OPs.

Referring to FIG. 13E, the substrate SUB may be removed, and the ink that remains in the ink supply part ISS may be removed to a lower portion of the ink supply part ISS depending on a pressure P-3 of the pressure applying part PAS.

N times that is the number of discharges of the ink INK may be set by the user. Here, N is a natural number of 2 or greater.

When the ink that remains in the ink supply part ISS is removed, the substrate SUB may not be disposed under the ink supply part ISS. The ink supply part ISS may be removed by discharging the remaining ink INK onto an ink purging part (not illustrated) of a stage STG, on which a substrate SUB is not disposed. While the stage STG reciprocates in the second direction DR2, the ink supply part ISS and the pressure applying part PAS may be disposed above the stage STG, on which the substrate SUB is not disposed.

The ink remaining in the ink supply part ISS may be provided to the ink purging part, and may be discharged to the outside. The ink INK provided to the ink purging part may be discharged to the outside through a discharge hole (not illustrated) of the ink purging part.

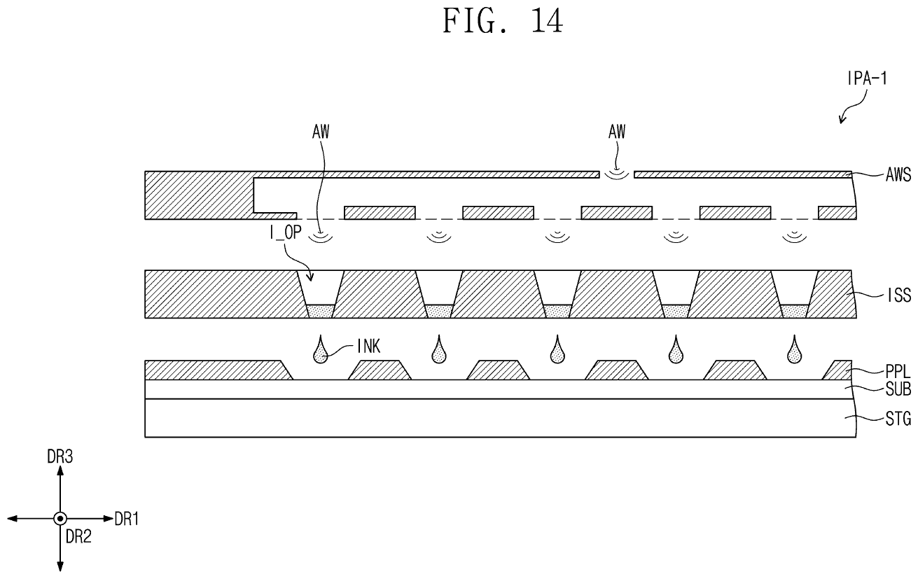

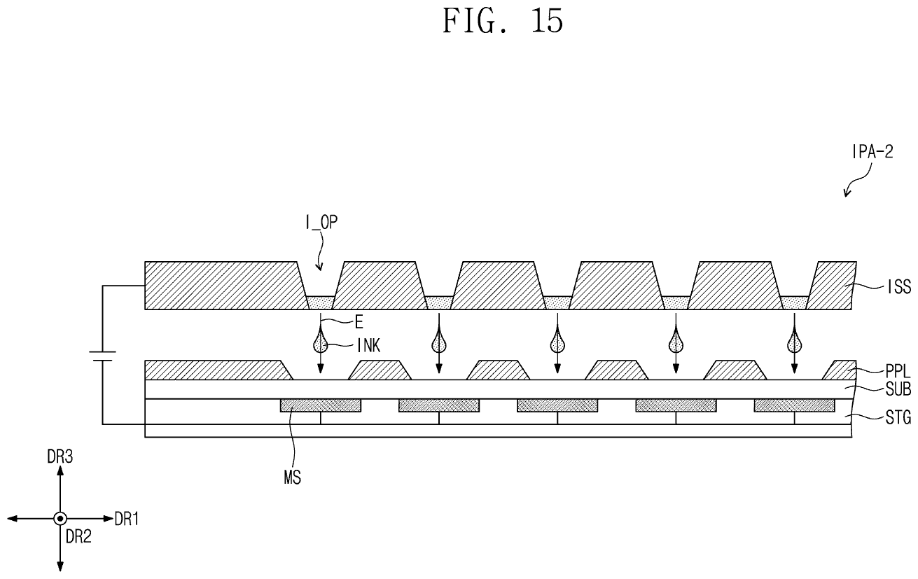

FIGS. 14 to 16 are views illustrating cross-sectional configurations of inkjet printing apparatuses according to embodiments of the disclosure. Particularly, FIGS. 14 to 16 are cross-sectional views corresponding to FIG. 13C. Hereinafter, configurations of inkjet printing apparatuses IPA-1, IPA-2, and IPA-3 will be described, focusing on a configuration that is different from that of the inkjet printing apparatuses IPA illustrated in FIG. 13C.

Referring to FIG. 14, an ultrasonic wave applying part AWS may be disposed above an upper surface of the ink supply part ISS. The ink supply part ISS and the ultrasonic wave applying part AWS may be disposed to be spaced apart from each other at a specific interval.

The ultrasonic wave applying part AWS may apply ultrasonic waves AW to the ink supply part ISS. The ultrasonic wave applying part AWS may generate ultrasonic waves AW by converting an electrical signal into vibration.

The ultrasonic wave applying part AWS may apply ultrasound waves AW to each of the openings I_OP. The ink INK may be discharged from the openings I_OP to the pixel openings OP.

Referring to FIG. 15, the stage STG may include metal layers MS. The metal layers MS may overlap the pixel openings OP.

A ground voltage may be applied to the stage STG, and a high voltage having a level that is higher than the ground voltage may be applied to the ink supply part ISS. In an embodiment, for example, the ink supply part ISS may be connected to the metal layers MS1. When a voltage is applied to the metal layers MS, an electric field may be formed toward the substrate SUB. As the voltage increases, an intensity of the electric field may become higher.

Electric forces (E) may be generated by the electric field, and the electric forces (E) may be applied to the ink INK. The ink INK may be discharged from the openings I_OP to the pixel openings OP by the electric forces (E).

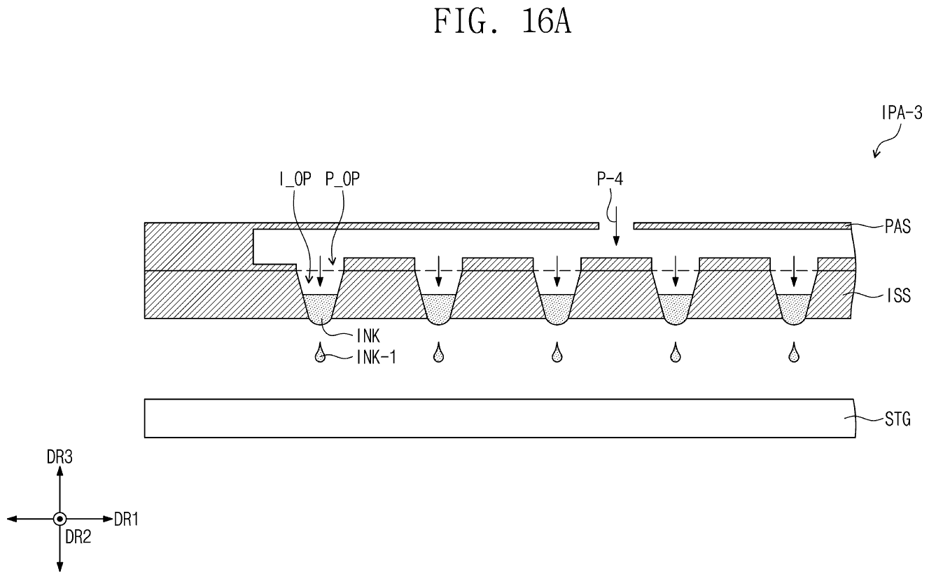

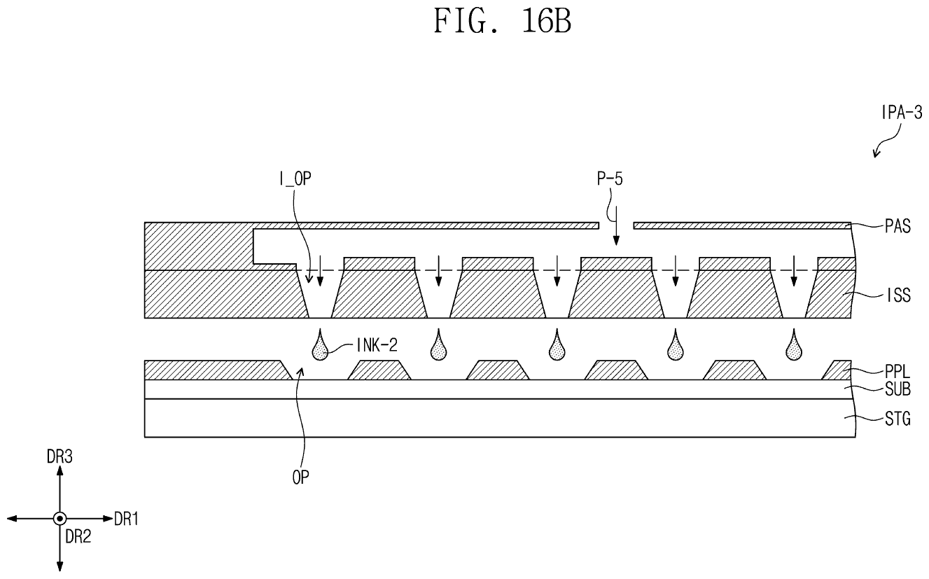

Referring to FIGS. 16A and 16B, some of the ink INK may be discharged onto the stage STG, on which a substrate is not disposed.

In such an embodiment of the ink supply part ISS, after some ink INK-1 is discharged, the substrate SUB may be disposed under the ink supply part ISS. Ink INK-2 that remains in the ink supply part ISS may be discharged to pixel openings OP1 to OP5.

In an embodiment, for example, an amount of some ink INK-1 may be smaller than an amount of the ink INK-2 that remains in the ink supply part ISS. Pressures P-4 applied to discharge some ink INK-1 may be lower than pressures P-5 applied to discharge remaining ink INK-2.

According to an embodiment of the disclosure, it is possible to control an intensity of the pressure applied by the pressure applying part to the ink supply part depending on a flow rate of the ink discharged from the ink supply part. In such an embodiment, the ink supply part may precisely control the amount of the ink discharged depending on the applied pressure, such that an increase in the size of the ink depending on drop power of the ink may be effectively prevented or substantially alleviated.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An inkjet printing apparatus comprising:
a stage, on which a substrate is disposed;
a head part disposed above the stage, wherein the head part includes a nozzle which discharges ink;
an ink supply part disposed between the stage and the head part, wherein an opening is defined through the ink supply part in a way such that the ink is received by the opening while overlapping the nozzle when viewed on a plane, and the ink supply part provides the ink onto the substrate through the opening; and
an ink flow rate measuring part connected to the ink supply part, wherein ink flow rate measuring part measures a flow rate of the ink discharged through the opening.

2. The inkjet printing apparatus of claim 1, wherein a width of the opening in a horizontal direction parallel to an upper surface of the ink supply part gradually decreases as going downward.

3. The inkjet printing apparatus of claim 1, wherein an inner surface of the ink supply part defining the opening includes an inclined surface.

4. The inkjet printing apparatus of claim 3, wherein the inner surface of the ink supply part defining the opening forms an acute angle with a lower surface of the ink supply part.

5. The inkjet printing apparatus of claim 4, wherein the inner surface of the ink supply part defining the opening forms an angle in a range of about 50 degrees to about 70 degrees with the lower surface of the ink supply part.

6. The inkjet printing apparatus of claim 1, wherein when viewed on the plane, the opening has a circular shape.

7. The inkjet printing apparatus of claim 1, wherein the ink supply part includes metal.

8. The inkjet printing apparatus of claim 1, further comprising:
a pressure applying part disposed to contact an upper surface of the ink supply part, wherein pressure applying part applies a pressure to the opening.

9. The inkjet printing apparatus of claim 8, further comprising:
a controller which controls the pressure applying part to adjust the pressure applied to the opening based on the flow rate of the ink.

10. The inkjet printing apparatus of claim 8, wherein the ink discharged through the opening is provided to a pixel opening defined in a pixel definition layer disposed on the substrate, and
wherein a width of a lower side of the opening defined on a lower surface of the ink supply part is smaller than a width of the pixel opening.

11. The inkjet printing apparatus of claim 8, wherein after the ink is discharged N times from the opening, the ink remaining in the ink supply part is removed to a lower side of the ink supply part based on the pressure of the pressure applying part, wherein N is a natural number of 2 or greater.

12. The inkjet printing apparatus of claim 1, wherein an amount of the ink discharged once from the opening is smaller than an amount of the ink discharged once from the nozzle.

13. The inkjet printing apparatus of claim 1, wherein a ground voltage is applied to the stage, and a high voltage having a higher level than the ground voltage is applied to the ink supply part.

14. The inkjet printing apparatus of claim 1, further comprising:
an ultrasonic wave applying part disposed on an upper surface of the ink supply part, wherein the ultrasonic wave applying part applies ultrasonic waves to the ink.

15. An inkjet printing method comprising:
disposing a head part including a nozzle above an ink supply part, in which an opening is defined;
providing ink discharged from the nozzle to the opening of the ink supply part;
disposing a pressure applying part on an upper surface of the ink supply part; and
discharging the ink from the opening toward a substrate by applying a pressure to the opening through the pressure applying part,
wherein a width of the opening in a horizontal direction parallel to an upper surface of the ink supply part gradually decreases as going downward.

16. The inkjet printing method of claim 15, wherein
an inner surface of the ink supply part defining the opening includes an inclined surface, and
the inner surface of the ink supply part defining the opening forms an acute angle with a lower surface of the ink supply part.

17. The inkjet printing method of claim 15, wherein an amount of the ink discharged once from the opening is smaller than an amount of the ink discharged once from the nozzle.

18. The inkjet printing method of claim 15, further comprising:
after the ink is discharged N times from the opening, removing the ink remaining in the ink supply part to a lower side of the ink supply part based on the pressure of the pressure applying part, wherein N is a natural number of 2 or greater.

19. The inkjet printing method of claim 15, wherein the ink discharged through the opening is provided to a pixel opening defined in a pixel definition layer disposed on the substrate, and
wherein a width of a lower side of the opening defined on a lower surface of the ink supply part is smaller than a width of the pixel opening.

20. The inkjet printing method of claim 15, further comprising:
before the ink is discharged to the substrate, preventing the ink from being discharged by applying a negative pressure to the opening through the pressure applying part.
